(19) United States
(12) Patent Application Publication
(10) Pub. No.: US 2026/0092365 A1
(43) Pub. Date: Apr. 2, 2026

(54) ACTIVATOR, AND SEMICONDUCTOR SUBSTRATE AND SEMICONDUCTOR DEVICE FABRICATED USING THE SAME

(71) Applicant: SOULBRAIN CO., LTD., Gyeonggi-do (KR)

(72) Inventors: Jae Sun JUNG, Gyeonggi-do (KR); Seung Hyun LEE, Gyeonggi-do (KR); Chang Bong YEON, Gyeonggi-do (KR)

(21) Appl. No.: 19/113,342

(22) PCT Filed: Oct. 6, 2023
(86) PCT No.: PCT/KR2023/015456

§ 371 Date: Mar. 19, 2025

(30) Foreign Application Priority Data
Oct. 7, 2022 (KR) 10-2022-0128694
Jan. 10, 2023 (KR) 10-2023-0003402
Jan. 13, 2023 (KR) 10-2023-0005228
Oct. 6, 2023 (KR) 10-2023-0133349

(51) Int. Cl. C23C 16/455

(52) U.S. Cl. CPC C23C 16/45534

(57) ABSTRACT

The present invention relates to an activator, and a semiconductor substrate and semiconductor device fabricated using the same. By using a titanium precursor compound and a specific reaction gas according to a method of manufacturing a titanium-containing deposition film of the present invention, a deposition film with high purity may be easily manufactured by a simple process.

### TECHNICAL FIELD

The present invention relates to an activator, and a semiconductor substrate and semiconductor device fabricated using the same. According to the present invention, by providing a compound containing a halogen different from a halogen ligand contained in a precursor compound as an activator, by enhancing the reactivity with the subsequently injected reactant through exchange with the halogen ligand in the precursor compound, the deposition reaction rate may be improved, the density and resistivity of a deposition film may be greatly improved, and impurities may be greatly reduced.

### BACKGROUND ART

In an ideal atomic layer deposition (ALD) process, the ligand of a precursor adsorbed on a substrate prevents the deposition of the subsequently injected precursor, based on a self-limiting reaction. However, in an actual process, the precursor may undergo thermal history, which may include some thermal decomposition, in which the ligand is released from a central metal. This process is a kind of chemical vapor deposition (CVD) character. As this character becomes stronger, step coverage and the density and thickness uniformity of a deposition film may decrease. In addition, there is also a problem that detached ligand species may remain as impurities in a deposited thin film when the detached ligand species are easily adsorbed to the surface as F, Cl, etc., or when the detached ligand species easily form fluoride or chloride (See J. Phys. Chem. B. 13491-8, “Surface chemistry in the atomic layer deposition of TiN films from TiCl₄ and ammonia” (2006))

The density and thickness uniformity of a deposition film are factors that affect the electrical and chemical properties. For example, electrical conductivity may be reduced, by-products (such as HCl) derived from the leaving group of a halogen ligand may be absorbed and contaminate the deposition film, or the crystal arrangement of the deposition film may be disrupted, further reducing the density.

Accordingly, it is important to reduce the thermal history of the precursor so that the process may take place within the atomic layer deposition (ALD) window. However, generally, the higher the deposition temperature, the better the film quality can be obtained. For example, when depositing a titanium nitride thin film, a thin film deposited at a higher temperature exhibits lower resistivity. To implement a thin film with low resistivity even when a deposition temperature is reduced, a deposition film with a complex structure can be formed by changing a first ligand of a precursor adsorbed on a substrate into a second ligand with higher reactivity and reacting the ligand with a reactant based on a self-limiting reaction. In addition, the thickness uniformity and deposition reaction rate of the deposition film may be improved, the residual impurities may be reduced, and the density may be greatly improved, thereby improving electrical properties such as resistivity. Accordingly, there is a need for development of a second ligand and a deposition film forming method using the same, and a semiconductor substrate and semiconductor device fabricated therefrom.

### DISCLOSURE

### Technical Problem

Therefore, the present invention has been made in view of the above problems, and it is one object of the present invention to provide an activator, and a semiconductor substrate and semiconductor device fabricated using the same. According to the present invention, by providing a compound of a predetermined structure as a second ligand to change a first ligand of a precursor compound, the deposition reaction rate and the thickness uniformity and density of a deposition film may be greatly improved, thereby improving electrical characteristics.

The above and other objects can be accomplished by the present invention described below.

### Technical Solution

In accordance with one aspect of the present invention, provided is an activator including an alkyl-free halogenide for changing a ligand of a precursor compound bonded to a group 4 central metal.

In accordance with another aspect of the present invention, provided is an activator including an alkyl-free halogenide for filling a ligand leaving site of a precursor compound bonded to a group 4 central metal.

When a halogen is included in the precursor compound, when the halogen is referred to as a first halogen, a halogen constituting the alkyl-free halogenide may be a second halogen that is different from the first halogen.

The first halogen may include one or more selected from fluorine, chlorine, iodine, and bromine.

The second halogen may include one or more selected from iodine and bromine.

The alkyl-free halogenide may form an intermediate to provide a deposition film in which a reactant-derived material is bonded to the group 4 metal.

The reactant-derived material may be provided from H₂O, H₂O₂, O₂, O₃, O radical, D₂, H₂, H radical, NH₃, NO₂, N₂O, N₂, N radical, H₂S, or S.

The intermediate may refer to a state in which a compound of a predetermined structure is provided as a second ligand to change a first ligand of a precursor compound.

The group 4 central metal may be titanium.

The alkyl-free halogenide may be an alkyl-free iodine donor, hydrogen iodide gas, hydrogen bromide gas, iodine ion, or iodine radical.

The deposition may be atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

In accordance with still another aspect of the present invention, provided is a semiconductor substrate in which a precursor adsorption state before ligand exchange on a substrate is -M-Xn (n=1˜3, X=F, Cl), and a precursor adsorption state after ligand exchange is -M-Ym (m=1˜3, Y=Br, I).

The change in precursor adsorption state before and after ligand exchange may be formed by a reaction between a precursor compound in which a first halogen is bonded to a group 4 central metal on the substrate; and an alkyl-free halogenide including a second halogen for filling a ligand leaving site of the above-described precursor compound.

The semiconductor substrate may include a deposition film formed through a process in which a first halogen atom (F or Cl) is substituted with a second halogen atom (Br or I) in the central metal (M) of Chemical Formula 1.

The deposition film may include a structure represented by Chemical Formula 2 below.

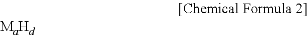

In Chemical Formula 1, M is a group 4 metal, H includes one or more of O, N, and S, a is an integer of 1, and d is 0 to 2.2.

The composition of the deposition film may be confirmed through XPS analysis.

The deposition film may have a multi-layer structure with two or more layers, a multi-layer structure with three or more layers, or a multi-layer structure with two or three layers.

The deposition film may have a deposition thickness of 500 Å or less as measured using an ellipsometer.

The deposition film may have a resistivity of 300 μΩ·cm or less.

The deposition film may have a density of 4.5 g/cm³ or more.

The deposition film may have an iodine atom of 50 counts/s or more as measured by SIMS.

The deposition film may be an oxide film, a nitride film, a metal film, or a sulfide film, and may be used as a diffusion barrier film, an etching stop film, an electrode film, a dielectric film, a gate insulating film, a block oxide film, or a charge trap.

In accordance with yet another aspect of the present invention, provided is a semiconductor device including the semiconductor substrate described above.

### Advantageous Effects

According to the present invention, the deposition reaction rate can be improved by changing the leaving group of a precursor adsorbed on a substrate to a second halogen. In addition, the productivity of a deposition film can be improved by appropriately increasing the thickness uniformity and density of the deposition film.

In addition, when forming a deposition film, the density is improved and process by-products are effectively reduced, so that corrosion or deterioration can be prevented, the crystallinity of the deposition film can be improved, and the electrical characteristics of the deposition film can be improved.

In addition, the thickness uniformity of a deposition film can be improved. In addition, a method of forming a deposition film and a semiconductor substrate and semiconductor device fabricated using the same can be provided.

### DESCRIPTION OF DRAWINGS

FIG. 1 is a diagram comparing the deposition thickness and resistivity measured for eight types of deposition films of Example 1 using an activator according to the present invention and 10 types of deposition films of Comparative Example 1 not using the activator.

FIG. 2 is a diagram comparing the contents of process by-products and impurities (Cl, O, Si, H, NH, metals, and metal oxides) measured by SIMS in Comparative Example 1 without using an activator.

FIG. 3 is a drawing comparing the contents of process by-products and impurities (Cl, O, Si, H, NH, metals, metal oxides) measured by SIMS in Example 1 using an activator according to the present invention.

### BEST MODE

Hereinafter, an activator of the present invention, and a semiconductor substrate and semiconductor device fabricated using the same are described in detail.

The present inventors confirmed that, by providing a specific compound as an activator capable of changing a ligand released from a precursor compound used to form a deposition film on the surface of a substrate loaded inside a chamber, the deposition reaction rate was improved, the thickness uniformity of the deposition film was secured, the density and resistivity of the deposition film were greatly improved, and Cl, O, Si, H, NH, metals, and metal oxides remaining as process by-products were reduced. Based on these results, the present inventors conducted further studies on the activator to complete the present invention.

Hereinafter, the activator, and the semiconductor substrate and semiconductor device including a deposition film manufactured using the same are described in detail.

### Activator

In the present invention, the activator may be a deposition additive compound used to form a deposition film on the surface of a substrate loaded inside a chamber and may be a predetermined compound capable of changing a ligand to be released.

For example, the precursor compound may be a compound in which a halogen is bonded to a group 4 central metal. Accordingly, during injection into a substrate to form a deposition film, a significant amount of the halogen is released, forming ligand leaving sites.

In the case where the activator used in the present invention is an alkyl-free halogenide, the activator may appropriately perform the role of filling the ligand leaving sites.

The term “alkyl-free”, unless otherwise specified, refers to not only not containing an alkyl group, but also not containing an alkene or alkyne group.

When a halogen constituting the precursor compound is a first halogen, a halogen constituting the alkyl-free halogenide may be a second halogen that is different from the first halogen.

The first halogen may include one or more selected from fluorine, chlorine, iodine, and bromine.

The second halogen may include one or more selected from iodine and bromine.

The activator may be a compound having a purity of preferably 99.9% or more, 99.95% or more, or 99.99% or more. For reference, when a compound having a purity of less than 99% is used, impurities may remain in a deposition film, or side reactions with the precursor or reactant may occur. Accordingly, it is preferable to use a compound having a purity of 99% or more.

Preferably, the activator may have a density of 1.0 to 4.0 g/cm³ or 2.0 to 3.4 g/cm³ and a vapor pressure of 1 atm at 180 to 240 K. Within this range, step coverage and the thickness uniformity, resistivity, and quality of a deposition film may be excellent.

The alkyl-free halogenide may form an intermediate to provide a deposition film having a structure in which a reactant-derived material is bonded to the group 4 metal.

Here, the reactant-derived material may be provided from H₂O, H₂O₂, O₂, O₃, O radical, D₂, H₂, H radical, NH₃, NO₂, N₂O, N₂, N radical, H₂S, or S.

The alkyl-free halogenide may include one or more selected from an alkyl-free iodine donor, hydrogen iodide gas, hydrogen bromide gas, iodine ion, and iodine radical. In this case, side reactions may be suppressed, and the growth rate of a deposition film may be regulated. Thus, process by-products within a deposition film may be reduced, corrosion or deterioration may be prevented, the crystallinity of a deposition film may be improved, and a stoichiometric oxidation state may be reached when forming a metal oxide film. Thus, even when a deposition film is formed on a substrate having a complex structure, step coverage and the thickness uniformity of a deposition film may be greatly improved.

As a specific example, the activator may be 3 N to 15 N hydrogen iodide, a gas mixture containing 1 to 99% by weight of 3 N to 15 N hydrogen iodide and an inert gas in an amount that allows a total weight to be 100% by weight, or an aqueous solution mixture containing 0.5 to 70% by weight of 3 N to 15 N hydrogen iodide and water in an amount that allows a total weight to be 100% by weight. Here, when the inert gas is nitrogen, helium, or argon with a purity of 4 N to 9 N, process by-products may be significantly reduced, step coverage may be excellent, deposition film density may be improved, and the electrical properties of a deposition film may be excellent.

Preferably, the activator may be 3 N to 7 N hydrogen iodide, a gas mixture containing 1 to 99% by weight of 5 N to 6 N hydrogen iodide and an inert gas in an amount that allows a total weight to be 100% by weight, or an aqueous solution mixture containing 0.5 to 70% by weight of 5 N to 6 N hydrogen iodide and water in an amount that allows a total weight to be 100% by weight. Here, the inert gas may be nitrogen, helium, or argon with a purity of 4 N to 9 N. In this case, by forming a substitution region that does not remain in a deposition film during deposition film formation, a relatively coarse deposition film may be formed while suppressing side reactions and controlling the growth rate of a deposition film. Thus, process by-products in a deposition film may be reduced, corrosion or deterioration may be prevented, and the crystallinity of a deposition film may be improved. Thus, even when a deposition film is formed on a substrate having a complex structure, step coverage and the thickness uniformity of a deposition film may be greatly improved.

In the present invention, the activator or precursor compound may be vaporized and injected, and then a plasma post-treatment step may be performed. In this case, the growth rate of a deposition film may be improved, and process by-products may be reduced.

The deposition may be atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

### Precursor Compound

In the present invention, the precursor compound used to form a deposition film is a molecule having a group 4 metal as a central metal atom (M) and one or more ligands of C, N, O, H, and X (halogen). When the precursor compound is a precursor having a vapor pressure of 1 mTorr to 100 Torr at 25° C., the effect of filling leaving sites with the activator described below may be maximized.

For example, the precursor compound may be a compound represented by Chemical Formula 1 below.

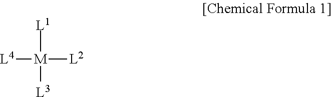

In Chemical Formula 1, M is a quaternary metal, and L1, L2, L3, and L4 are the same or different as —H, —X, —R, —OR, or —NR₂ and include at least one —X. Here, —X is F, Cl, or Br, and —R is C1-C10 alkyl, C1-C10 alkene, or C1-C10 alkane and is linear or cyclic.

In Chemical Formula 1, M is titanium (Ti). In this case, process by-products may be significantly reduced, step coverage may be excellent, the density of a deposition film may be improved, and the electrical characteristics and insulating properties of a deposition film may be excellent.

In Chemical Formula 1, L1, L2, L3, and L4 are —H or —X, may be the same or different, and include at least one —X. Here, —X may be F, Cl, or Br.

In addition, for example, a titanium precursor compound may have a structure represented by Chemical Formula 1-1 below, or a structure represented by Chemical Formula 1-2 below.

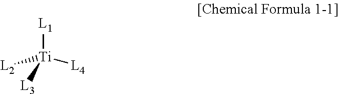

L1 may be H, F, Cl, Br, Me, Et, iPr, OMe, OEt, NMe₂, NEt₂, or NMeEt.

L2 may be H, F, Cl, Br, Me, Et, iPr, OMe, OEt, NMe₂, NEt₂, or NMeEt.

L3 may be H, F, Cl, Br, Me, Et, iPr, OMe, OEt, NMe₂, NEt₂, or NMeEt.

L4 may be H, F, Cl, Br, Me, Et, iPr, OMe, OEt, NMe₂, NEt₂, or NMeEt.

L1 to L4 may be the same or different.

In the present disclosure, unless otherwise specified, Me represents a methyl group, and Et represents an ethyl group.

For example, the structure represented by Chemical Formula 1-1 may be TiCl₄, TiBr₄, Ti(OMe)₄, or Ti(NMe₂)₄.

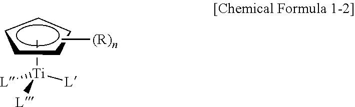

L′, L″, and L′″ may be independently OMe, OEt, NMe2, NEt2, or NMeEt.

R may be Me or Et.

n may be an integer from 0 to 5.

For example, the compound represented by Chemical Formula 1-2 may be CpMeTi(OMe)₃, CpMe₂Ti(OMe)₃, CpMe₃Ti(OMe)₃, CpMe₄Ti(OMe)₃, CpMe₅Ti(OMe)₃, CpMeTi(OEt)₃, CpMe₂Ti(OEt)₃, CpMe₃Ti(OEt)₃, CpMe₄Ti(OEt)₃, CpMe₅Ti(OEt)₃, CpMeTi(NMe₂)₃, CpMe₂Ti(NMe₂)₃, CpMe₃Ti(NMe₂)₃, CpMe₄Ti(NMe₂)₃, CpMe₅Ti(NMe₂)₃, CpMeTi(NEt₂)₃, CpMe₂Ti(NEt₂)₃, CpMe₃Ti(NEt₂)₃, CpMe₄Ti(NEt₂)₃, CpMe₅Ti(NEt₂)₃, CpMeTi(NMeEt)₃, CpMe₂Ti(NMeEt)₃, CpMe₃Ti(NMeEt)₃, CpMe₄Ti(NMeEt)₃, or CpMe₅Ti(NMeEt)₃.

In the present invention, for example, the precursor compound may be mixed with a non-polar solvent and introduced into the chamber. In this case, the viscosity or vapor pressure of the precursor compound may be easily controlled.

The non-polar solvent may preferably include one or more selected from the group consisting of alkanes and cycloalkanes. In this case, an organic solvent with low reactivity and solubility and easy moisture management may be included. In addition, step coverage may be improved even when deposition temperature increases during deposition film formation.

As a more preferred example, the non-polar solvent may include a C1 to C10 alkane or a C3 to C10 cycloalkane, preferably a C3 to C10 cycloalkane. In this case, reactivity and solubility may be reduced, and moisture management may be easy.

In the present disclosure, C1, C3, and the like indicate the number of carbon atoms.

The cycloalkane may preferably include C3 to C10 and monocycloalkanes, among the monocycloalkanes, cyclopentane is liquid at room temperature and has the highest vapor pressure, so cyclopentane is preferable in the vapor deposition process, but the present invention is not limited thereto.

For example, the non-polar solvent may have a solubility (25° C.) of 200 mg/L or less, preferably 50 to 400 mg/L, more preferably 135 to 175 mg/L in water. Within this range, the reactivity toward the precursor compound may be reduced, and moisture may be easily managed.

In the present disclosure, solubility may be measured without any particular limitation by a measurement method or standard commonly used in the technical field to which the present invention pertains. For example, solubility may be measured by the HPLC method using a saturated solution.

Based on a total weight of the precursor compound and the non-polar solvent, the non-polar solvent may be included in an amount of 5 to 95% by weight, more preferably 10 to 90% by weight, still more preferably 40 to 90% by weight, most preferably 70 to 90% by weight.

When the content of the non-polar solvent exceeds the above range, impurities may be generated, which may increase the resistance and impurities within a deposition film. When the content of the organic solvent is less than the range, the effect of improving step coverage due to solvent addition and the effect of reducing impurities such as chloride (Cl) ions may be reduced.

### Deposition Film

A deposition film obtained using the activator described above is included.

The deposition film may have a multi-layer structure with two or more layers.

For example, the deposition: film may include a structure in which a group 4 metal is bonded to a reactant-derived material and a second halogen.

The deposition film may have a deposition thickness of 170 Å or less or 100 to 170 Å as measured by SIMS.

The deposition film may have a resistivity of 300 μΩ·cm or less or 150 to 300 μΩ·cm. Within this range, electrical conductivity may be improved.

The deposition film may have a deposition rate of 0.34 Å/cycle or more or 0.34 to 0.535 Å/cycle.

The deposition film may have a density of 4.8 g/cm³ or more or 4.8 to 5.3 g/cm³.

The deposition film may have a deposition rate increase rate of 10% or more, as a specific example, 12.5% or more, preferably 15% or more as calculated by Equation 1 below. In this case, a deposition film is formed by the activator having the aforementioned structure, and at the same time, the growth rate of a deposition film formed is greatly reduced, so that even when applied to a substrate having a complex structure, the uniformity of the deposition film may be secured, and the step coverage may be greatly improved. In particular, deposition in a thin thickness is possible, and the remaining amounts of O, Si, metals, and metal oxides remaining as process by-products may be reduced. In addition, even the remaining amount of carbon, which was difficult to reduce in the past, may be reduced.

$$Deposition rate increase rate = [ ( {DR}_{f} ) / ( {DR}_{i} ) ] \times 100 \qquad [ Equation 1 ]$$

In Equation 1, the deposition rate (DR, Å/cycle) is the speed at which a deposition film is deposited. In the deposition of a deposition film formed from a precursor and a reactant, DRᵢ (initial deposition rate) is the deposition rate of the deposition film formed without adding an activator. DR_{f} (final deposition rate) is the deposition rate of the deposition film formed by adding an activator during the above process. Here, the deposition rate (DR) is a value measured at room temperature and pressure using an ellipsometer for a deposition film with a thickness of 1 to 30 nm, and is expressed in a unit of Å/cycle.

In Equation 1, when the activator is used and when the activator is not used, the growth rate of a deposition film per cycle means the deposition film deposition thickness per each cycle (Å/cycle), i.e., deposition rate. For example, the deposition rate may be calculated by measuring the final thickness of a deposition film at room m temperature under normal pressure using an ellipsometer for a deposition film with a thickness of 1 to 30 nm, and then dividing the final thickness by the total number of cycles to obtain an average deposition rate.

In Equation 1, “when the activator is not used” refers to a case where a deposition film is formed by adsorbing only a precursor compound on a substrate during the process of depositing a deposition film, as a specific example, a case where a deposition film is formed by omitting the step of adsorbing an activator and the step of purging an unadsorbed activator in the method of forming a deposition film.

The deposition film may provide a metal film, an oxide film, a nitride film, a sulfide film, or a chalcogenide. In this case, the effects desired in the present invention may be sufficiently achieved.

The deposition film may include the aforementioned film composition alone or as a selective area, but is not limited thereto, and also includes SiH and SiOH.

In addition to commonly used diffusion barrier films, the deposition film may be used as an etching stop film, an electrode film, a dielectric film, a gate insulating film, a block oxide film, or a charge trap in a semiconductor device.

For example, the deposition film may include a halogen compound in an amount of 10,500 counts/s or less as measured by SIMS.

### Method of Manufacturing Deposition Film

The deposition film may be manufactured in a variety of ways, for example, by the following method:

As a first step, a precursor compound including a group 4 metal and a first halogen may be injected onto a substrate loaded in a chamber.

For example, the first halogen may include one or more selected from fluorine, chlorine, iodine, and bromine, preferably chlorine having excellent reactivity.

In the present disclosure, for example, the precursor compound may be transferred to the deposition chamber by a vapor flow control (VFC) method of transferring vaporized gas by using a mass flow controller (MFC) method, a mass flow controller (MFC) method such as a liquid mass flow controller (LMFC) method, or a liquid delivery system (LDS) method of transferring liquid.

At this time, a mixed gas of one or more selected from the group consisting of argon (Ar), nitrogen (N₂), and helium (He) may be used as a carrier gas or dilution gas to move the precursor compound onto the substrate, without being limited thereto.

In the present disclosure, for example, an inert gas, preferably the carrier gas or dilution gas may be used as the purge gas.

The chamber may be an atomic layer deposition (ALD) chamber, a plasma-enhanced atomic layer deposition (PEALD) chamber, a chemical vapor deposition (CVD) chamber, a plasma-enhanced chemical vapor deposition (PECVD) chamber, a metalorganic chemical vapor deposition (MOCVD) chamber, or a low pressure chemical vapor deposition (LPCVD) chamber.

The substrate loaded into the chamber may include a semiconductor substrate such as a silicon substrate or silicon oxide.

The substrate may further have a conductive layer or insulating layer formed thereon.

The substrate may be maintained at 50 to 500° C., or 80 to 500° C.

For example, the substrate may be heated to 50 to 500° C., as a specific example, 80 to 500° C., 100 to 800° C., or 200 to 500° C. The activator or precursor compound may be injected onto the substrate in an unheated or heated state, and depending on the deposition efficiency, the activator or precursor compound may be injected in an unheated state and then the heating conditions may be adjusted during the deposition process. For example, the activator or precursor compound may be injected onto the substrate heated to 300 to 600° C. for 1 to 20 seconds.

Regarding the amount (mg/cycle) of the precursor compound injected into the chamber, the input amount (mg/cycle) ratio of the activator used in the second step described below to the precursor compound injected into the chamber may be, for example, 1:1 to 1:20, preferably 1:1 to 1:15, more preferably 1:1 to 1:10. Within this range, step coverage may be greatly improved, and process by-products may be significantly reduced.

The first step may include one or more purging steps using an inert gas. The inert gas may be the carrier gas or dilution gas described above.

The amount of purge gas injected into the chamber in the step of purging the unabsorbed precursor compound is not particularly limited as long as the amount is sufficient to remove the unabsorbed precursor compound, and may be, for example, may be 10 to 100,000 times, preferably 50 to 50,000 times, more preferably 100 to 10,000 times the volume of the precursor compound injected into the chamber. Within this range, by sufficiently removing the unabsorbed precursor compound, a deposition film may be formed evenly and deterioration of film quality may be prevented. Here, the input amounts of the purge gas and precursor compound are each based on one cycle, and the volume of the precursor compound refers to the volume of the vaporized precursor compound.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the growth rate of a deposition film per cycle may be appropriately controlled. In addition, since deposition is performed as an atomic mono-layer or nearly an atomic mono-layer, the film quality may be improved.

As a second step, an alkyl-free halogenide containing a second halogen different from the first halogen is introduced onto the substrate so that the first halogen changes the leaving site into the second halogen. In this case, the leaving group of the precursor adsorbed on the substrate may be effectively changed to improve the reaction rate. In addition, by appropriately reducing the growth rate of a deposition film, even when forming a deposition film on a substrate having a complex structure, step coverage, resistivity, and the thickness uniformity of a deposition film may be greatly improved.

For example, the second halogen may include one or more selected from iodine and bromine, preferably iodine.

The feeding time (sec) of the activator on the surface of the substrate may be preferably 0.001 to 10 seconds, more preferably 0.02 to 3 seconds, still more preferably 0.04 to 2 seconds, still more preferably 0.05 to 1 second per cycle. Within this range, the growth rate of a deposition film may be increased, and step coverage and economic efficiency may be excellent.

In the present disclosure, the feeding time of the activator is based on a flow rate of 1 to 500 sccm at a chamber volume of 15 to 20 L, and more specifically, based on a flow rate of 10 to 200 sccm at a chamber volume of 18 L.

In the present disclosure, for example, the activator may be delivered into the deposition chamber by vapor flow control (VFC) using a mass flow controller (MFC).

The second step may include one or more purging steps using an inert gas. In the present disclosure, as the purge gas, for example, a carrier gas or a dilution gas may be used.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the growth rate of a deposition film per cycle may be appropriately controlled. In addition, since deposition is performed as an atomic mono-layer or nearly an atomic mono-layer, the film quality may be improved.

The amount of purge gas injected into the chamber in the step of purging the unadsorbed activator is not particularly limited as long as the amount is an amount sufficient to remove the unadsorbed activator, but may be, for example, 10 to 100,000 times, preferably 50 to 50,000 times, more preferably 100 to 10,000 times. Within this range, by sufficiently removing the unadsorbed activator, a deposition film may be evenly formed, and deterioration of film quality may be prevented. Here, the input amounts of the purge gas and activator are each based on one cycle, and the volume of the activator refers to the volume of the vaporized activator.

As a specific example, the activator is injected at a flow rate of 100 sccm and an injection time of 0.5 sec (per cycle). In the step of purging an unadsorbed activator, when the purge gas is injected at a flow rate of 3000 sccm and an injection time of 5 seconds (per cycle), the amount of purge gas injected is 300 times the amount of activator injected.

Next, as a third step, a reactant may be injected into the substrate to form a group 4 metal-derived deposition film.

For example, the reactant may be a gas including H₂O, H₂O₂, O₂, O₃, O radical, D₂, H₂, H radical, NH₃, NO₂, N₂O, N₂, N radical, H₂S, or S.

The deposition film may include a structure in which a group 4 metal is bonded to a reactant-derived material and a second halogen.

For example, the method of forming a deposition film may be performed at a deposition temperature of 50 to 800° C., preferably 100 to 700° C., more preferably 200 to 650° C., still more preferably 220 to 500° C. Within this range, process characteristics may be implemented and a deposition film having excellent film quality may be formed.

For example, the method of forming a deposition film may be performed under a deposition pressure of 0.01 to 20 Torr, preferably 0.1 to 20 Torr, more preferably 0.1 to 10 Torr, most preferably 0.3 to 7 Torr. Within this range, a deposition film with uniform thickness may be obtained.

In the present disclosure, the deposition temperature and the deposition pressure may be measured as temperature and pressure formed within the deposition chamber, or as temperature and pressure applied to the substrate within the deposition chamber.

The second step may preferably include a step of increasing the temperature inside the chamber to the deposition temperature before introducing the activator into the chamber; and/or a step of purging by injecting an inert gas into the chamber before introducing the activator into the chamber.

The third step may include a purging step using an inert gas.

In the purging step performed immediately after the reaction gas supply step, the amount of purge gas introduced into the chamber may be, for example, 10 to 10,000 times, preferably 50 to 50,000 times, more preferably 100 to 10,000 times the volume of reaction gas introduced into the chamber. Within this range, the desired effects may be sufficiently achieved. Here, the input amounts of purge gas and reaction gas are based on one cycle.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the growth rate of a deposition film per cycle may be appropriately controlled. In addition, since deposition is performed as an atomic mono-layer or nearly an atomic mono-layer, the film quality may be improved.

In the method of forming a deposition film, when necessary, the unit cycle may be repeated 1 to 99, 999 times, preferably 10 to 10,000 times, more preferably 50 to 5,000 times, still more preferably 100 to 2,000 times. Within this range, the desired thickness of a deposition film may be obtained, and the effects desired in the present invention may be sufficiently achieved.

As a specific example, in the method of manufacturing a deposition film, to deposit a deposition film on a substrate positioned in the chamber, the above-described activator and a precursor compound or a mixture of the precursor compound and a non-polar solvent are prepared, respectively.

Then, the prepared precursor compound or a mixture of the precursor compound and a non-polar solvent is injected into a vaporizer, changes into a vapor phase, is transferred to a deposition chamber, and is adsorbed on the substrate. Then, the ligand of the precursor compound is replaced by the pre-injected activator, and the unabsorbed precursor compound is purged.

Next, the prepared activator is injected into the vaporizer, changed into a vapor phase, transferred to the deposition chamber, and adsorbed onto the substrate. Then, purging is performed to remove the unabsorbed activator.

In the present disclosure, for example, the activator and precursor compound may be transferred to the deposition chamber by a vapor flow control (VFC) method of transferring vaporized gas by using a mass flow controller (MFC) method or a liquid delivery system (LDS) method of transferring a liquid by using a liquid mass flow controller (LMFC) method.

At this time, a mixed gas of one or more selected from the group consisting of argon (Ar), nitrogen (N₂), and helium (He) may be used as a carrier gas or dilution gas to move the activator and the precursor compound onto the substrate, without being limited thereto.

In the present disclosure, for example, an inert gas, preferably the carrier gas or dilution gas may be used as the purge gas.

Next, a reactant is supplied. As the reactant, a reaction gas commonly used in the technical field to which the present invention pertains may be used in the present invention without particular limitation. Preferably, the reactant may include a nitriding agent. The nitriding agent and the precursor compound adsorbed on the substrate react to form a nitride film.

Preferably, the nitriding agent may be nitrogen gas (N₂), hydrazine gas (N₂H₄), or a mixture of nitrogen gas and hydrogen gas.

Next, unreacted residual reaction gas is purged using an inert gas. Accordingly, in addition to excess reaction gas, generated byproducts may also be removed.

As described above, in the method of forming a deposition film, for example, a step of adsorbing a precursor compound onto a substrate, a step of purging an unabsorbed precursor compound, a step of supplying an activator onto a substrate, a step of purging an unabsorbed activator, a step of supplying a reaction gas, and a step of purging a residual reaction gas may be set as an unit cycle. To form a deposition film of desired thickness, the unit cycle may be repeated.

For example, the unit cycle may be repeated 1 to 99,999 times, preferably 10 to 1,000 times, more preferably 50 to 5,000 times, still more preferably 100 to 2,000 times. Within this range, the desired deposition thin film properties may be well expressed.

When the injection time of the precursor compound and the purge time in the first step are a and b, respectively, the injection time of the alkyl-free halogenide and the purge time in the second step are c and d, respectively, and the injection time of the reactant and the purge time in the third step are e and f, respectively, 0.1≤a≤10, 2a≤b≤4a, 0.1<c≤10, 2c≤d≤8c, 2<e≤10, and 2e≤b≤8e may be satisfied at the same time.

When the injection and purge of the precursor compound and alkyl-free halogenide and the injection and purge of the reactant are considered as one cycle, all of the following four conditions may be satisfied: 1) The deposition film has a deposition thickness of 500 Å or less as measured using an ellipsometer. 2) The deposition film has a resistivity of 300 μΩ·cm or less. 3) The deposition film has a deposition rate of 0.34 Å/cycle or more. 4) The deposition film has a density of 4.5 g/cm³ or more.

The deposition film may have a deposition thickness of 500 Å or less, or 2 to 300 Å, more preferably 5 to 250 Å as measured using an ellipsometer.

The deposition film may have a resistivity of 300 μΩ·cm or less, or 10 to 300 μΩ·cm, preferably 30 to 200 μΩ·cm.

The deposition film may have a density of 4.5 g/cm³ or more, or 4.5 to 5.5 g/cm³.

The deposition film may contain an iodine atom in an amount of 50 counts/s or more as measured by SIMS.

When the injection and purge of the precursor compound and alkyl-free halogenide and the injection and purge of the reactant are considered as one cycle, all of the following four conditions may be satisfied: 1) The deposition film has a deposition thickness of 100 to 500 Å as measured using an ellipsometer. 2) The deposition film has a resistivity of 150 to 300 μΩ·cm. 3) The deposition film has a deposition rate of 0.34 to 0.535 Å/cycle. 4) The deposition film has a density of 4.8 to 5.5 g/cm³.

For example, the method of manufacturing a deposition film may be performed using a deposition film manufacturing apparatus including an ALD chamber, a first vaporizer for vaporizing an activator, a first transport means for transporting the vaporized activator into the ALD chamber, a second vaporizer for vaporizing a deposition film precursor, and a second transport means for transporting the vaporized deposition film precursor into the ALD chamber. Here, the vaporizer and transport means are not particularly limited as long as the vaporizer and transport means are a vaporizer and transport means commonly used in the technical field to which the present invention belongs.

### Semiconductor Substrate

In addition, the present invention provides a semiconductor substrate. The semiconductor substrate is fabricated using the method of forming a deposition film of the present invention or includes the deposition film. In this case, the step coverage and thickness uniformity of a deposition film may be excellent, and the density and electrical characteristics of a deposition film may be excellent.

As a specific example, the semiconductor substrate according to the present invention may provide a semiconductor substrate in which a precursor adsorption state before ligand exchange on a substrate is -M-Xn (n=1˜3, X=F, Cl), and a precursor adsorption state after ligand exchange is -M-Ym (m=1˜3, Y=Br, I).

The change in precursor adsorption state before and after ligand exchange may occur by the reaction between a precursor compound in which a first halogen is bonded to a group 4 central metal on the substrate; and an alkyl-free halogenide containing a second halogen to fill the ligand leaving site of the aforementioned precursor compound.

For example, the semiconductor substrate may include a deposition film formed through a process in which a first halogen atom (F or Cl) is substituted with a second halogen atom (Br or I) in the central metal (M) of Chemical Formula 1.

For example, when necessary, the deposition film may have a multilayer structure of two or more layers, a multilayer structure of three or more layers, or a multilayer structure of two or three layers. As a specific example, the multilayer film with a two-layer structure may have a lower layer-middle layer structure, and the multilayer film with a three-layer structure may have a lower layer-middle layer-upper layer structure.

As a specific example, the deposition film may be a deposition film (TiN electrode for DRAM or barrier film for NAND).

For example, the lower layer may be formed of one or more selected from the group consisting of Si, SiO₂, MgO, Al₂O₃, Cao, ZrSiO₄, ZrO₂, HfSiO₄, Y₂O₃, HfO₂, LaLuO₂, Si₃N₄, SrO, La₂O₃, Ta₂O₅, Bao, and TiO₂.

For example, the upper layer may be formed of one or more selected from the group consisting of W and Mo.

### Semiconductor Device

According to the present invention, a semiconductor device including the semiconductor substrate described above may be provided.

For example, the semiconductor device may be low-resistive metal gate interconnects, a high-aspect-ratio 3D metal-insulator-metal (MIM) capacitor, a DRAM trench capacitor, 3D Gate-All-Around (GAA), or 3D NAND flash memory.

Hereinafter, the present invention will be described in more detail with reference to the following preferred examples. However, these examples are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

TiCl₄ as a precursor compound was prepared.

5 N HI as an activator was prepared.

An ALD deposition process was performed using the precursor compound and activator with the deposition process sequence according to the present invention as one cycle.

The specific experimental methods for Example 1 and Comparative Example are as follows.

### Example 1 (Examples 1-1 to 1-8)

TiCl₄ as a precursor compound was placed in a canister and supplied to a separate vaporizer heated to 150° C. at a flow rate of 0.05 g/min using a liquid mass flow controller (LMFC) at room temperature. TiCl₄ vaporized from the vaporizer was injected into a deposition chamber for 1 second using a vapor flow controller (VFC), and then argon gas was supplied at 3000 sccm for 5 seconds to perform argon purging. At this time, the pressure inside the reaction chamber was controlled to 2.5 Torr.

Next, 5 N HI as an activator was placed in a canister and supplied to a vaporizer heated to 150° C. at a flow rate of 0.05 g/min using a mass flow controller (MFC) at room temperature. The activator vaporized from the vaporizer was injected into a deposition chamber loaded with a substrate for 2 seconds using a vapor flow controller (VFC), and then argon gas was supplied at 3000 sccm for 5 seconds to perform argon purging. At this time, the pressure inside the reaction chamber was controlled to 2.5 Torr.

Next, ammonia as a reactive gas was injected into the reaction chamber at 1000 sccm for 3 seconds, followed by argon purging for 9 seconds. At this time, the substrate on which a deposition film is to be formed was heated to 460° C.

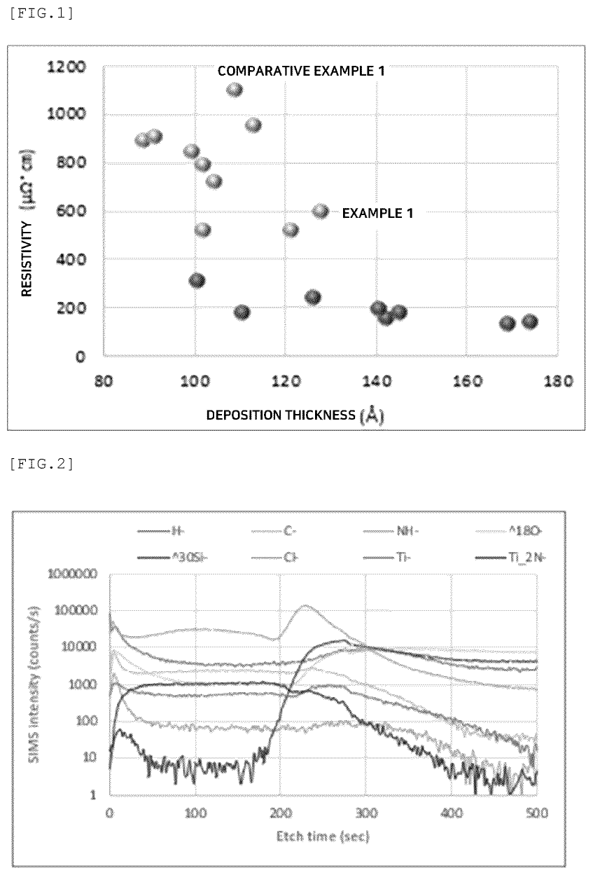

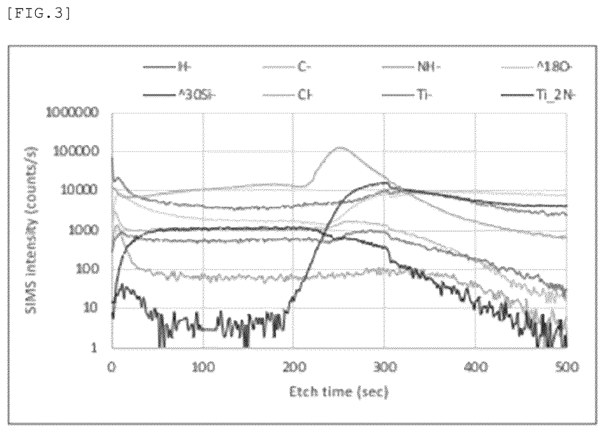

By repeating this process 200 to 400 times, eight types of deposition films having deposition thicknesses shown in FIG. 1, which are self-limiting atomic layers, were formed.

As shown in FIG. 1 below, the deposition thicknesses of the deposition films were 100 Å, 110 Å, 125 Å, 140 Å, 142 Å, 144 Å, 170 Å, and 175 Å, respectively.

The deposition thickness of the manufactured deposition film was measured using an ellipsometer, which is a device capable of measuring optical properties such as the thickness or refractive index of a deposition film by using the polarization characteristics of light.

In addition, the deposition rate increase rate (D/R (dep. rate) increase rate) was calculated for the eight types of deposition films. Specifically, the thickness of the deposition film deposited per cycle was calculated by dividing the thickness of the deposition film by the number of cycles, and the reduction rate in the deposition film growth rate was calculated. Specifically, the calculation was performed using Equation 1 described above.

The average calculated deposition rate increase rate for the eight types was 0.535 Å/cycle.

In addition, resistivity was measured for the eight types of deposition films, and the results are shown in FIG. 1 below.

The resistivity was measured by considering surface resistance measured by a surface resistance meter and thickness measured by an ellipsometer.

In addition, the resistivity values for deposition thicknesses of 100 to 130 Å were 176 Ω·cm, 239 Ω·cm, and 302 Ω·cm, and the average thereof was 239 Ω·cm.

In addition, the density of the eight types of deposition films was measured using X-ray reflectometry (XRR) equipment.

The average of the eight measured densities was 4.68 g/cm³.

In addition, the impurity contents of the eight types of deposition films were measured.

Here, impurities, such as H, C, NH, 180, Cl, and Ti, were measured using secondary-ion mass spectrometry (SIMS) equipment.

Specifically, the impurity value was verified in the SIMS graph by considering the impurity content (counts) when an ion sputter was used to axially dig into the deposition film and the sputter time was 50 seconds with little contamination on the surface of a substrate.

The verified SIMS results are presented as a graph in FIG. 2 below. Specifically, the average impurity content of Cl— in the eight types of deposition films was calculated as 10,406 counts/s.

In addition to Cl—, reduction of O, Si, H, NH, metals, and metal oxides remaining as process by-products was be confirmed through FIG. 1.

### Comparative Example 1

The same process as in Example 1 was performed except that, instead of 5 N HI used as an activator in Example 1, 5 N HCl was used.

As a result, Cl impurities increased or etching occurred at very low densities.

For reference, when a plasma atmosphere of HCl or Cl₂ is formed on a TiN substrate or a high temperature condition equivalent thereto is provided, there is a problem that TiN can be etched (dry etching).

### Comparative Example 2

The same process as in Example 1 was performed except that 5 N HI used as an activator in Example 1 was not used, and 10 types of deposition films were manufactured. The measurement results are shown in FIGS. 1 and 2.

As shown in FIG. 1 below, the deposition thicknesses of the deposition films were 88 Å, 90 Å, 100 Å, 101 Å, 102 Å, 104 Å, 109 Å, 111 Å, 121 Å, and 127 Å, respectively.

In addition, the deposition rate increase rate (D/R (dep. rate) increase rate) was calculated for the 10 types of deposition films.

The average deposition rate increase rate of the 10 types was calculated to be 0.34 Å/cycle.

As a result, it was confirmed that Comparative Example 2 was about 30% defective compared to Example 1.

In addition, resistivity was measured for the 10 types of deposition films.

As shown in FIG. 1, the resistivity values of the deposition films were 515 μΩ·cm, 517 μΩ·cm, 592 μΩ·cm, 650 μΩ·cm, 800 μΩ·cm, 802 μΩ·cm, 890 μΩ·cm, 900 μΩ·cm, 970 μΩ·cm, 11100 μΩ·cm, respectively, showing an average value of 715 μΩ·cm. As a result, it was confirmed that Comparative Example 2 was about 15% defective compared to Example 1.

In addition, the resistivity values for deposition thicknesses of 100 to 130 Å were 515 μΩ·cm, 517 μΩ·cm, and 592 μΩ·cm, and the average was calculated to be 541 μΩ·cm.

In addition, the density of the 10 deposition films was measured using X-ray reflectometry (XRR) equipment. The average density of the 10 measured films was 5.03 g/cm³. As a result, it was confirmed that Comparative Example 2 was about 9% defective compared to Example 1.

In addition, the impurity contents of the 10 deposition films were measured, and the SIMS results are shown in a graph in FIG. 2. Specifically, the average impurity content of Cl— in the 10 deposition films was 31,638 counts/s. As a result, it was confirmed that Comparative Example 2 was about 50% or less defective compared to Example 1.

Based on these results, in the case of Examples 1 to 2 according to the present invention using a precursor ligand and a different type of activator, comparative Example 1, which used the same type of activator as the precursor ligand, and Comparative Example 2, which did not use any activator at all, deposition thickness, deposition rate increase rate, and resistivity were all significantly improved, and impurity reduction characteristics were excellent.

In particular, in the case of Example 1, which used an activator according to the present invention, compared to Comparative Example 2, which did not use the activator, the deposition rate increase rate per cycle of the deposition film and the density of the deposition film were 10% or more, respectively. Resistivity reduction rate was 50% or more, and impurity reduction rate was 60% or more, showing excellent resistivity reduction rate and impurity reduction rate.

Therefore, when using a compound of a different type from the ligand of the precursor compound as the activator of the present invention, the thickness, deposition rate increase rate, density, and resistivity of the deposition film were improved through the ligand exchange mechanism. In addition, impurity reduction characteristics was excellent. Accordingly, a deposition film was effectively formed even on a substrate with a complex pattern.

1. An activator comprising an alkyl-free halogenide for changing a ligand of a precursor compound bonded to a group 4 central metal.

2. The activator according to claim 1, wherein, when a halogen is comprised in the precursor compound, when the halogen is referred to as a first halogen, a halogen constituting the alkyl-free halogenide is a second halogen that is different from the first halogen.

3. The activator according to claim 2, wherein the first halogen is a precursor having one or more ligands selected from fluorine, chlorine, and bromine.

4. The activator according to claim 2, wherein the second halogen comprises one or more selected from iodine and bromine.

5. The activator according to claim 1, wherein the group 4 central metal is titanium.

6. The activator according to claim 1, wherein the alkyl-free halogenide is an alkyl-free iodine donor, hydrogen iodide gas, hydrogen bromide gas, iodine ion, or iodine radical.

7. The activator according to claim 1, wherein the deposition is atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

8. A semiconductor substrate comprising a structure in which a ligand of the precursor compound is changed using the activator comprising an alkyl-free halogenide according to claim 1 on a substrate.

9. The semiconductor substrate according to claim 8, wherein a structure represented by Chemical Formula 1 is formed by a reaction between a precursor compound in which a first halogen is bonded to a group 4 central metal on the substrate; and an alkyl-free halogenide comprising a second halogen for filling a ligand leaving site of the precursor compound.

10. The semiconductor substrate according to claim 8, wherein the semiconductor substrate comprises a deposition film having a structure in which a reactant-derived material and a second halogen are combined with a quaternary central metal (M) of Chemical Formula 1.

11. The semiconductor substrate according to claim 10, wherein the reactant-derived material is provided from H₂O, H₂O₂, O₂, O₃, O radical, D₂, H₂, H radical, NH₃, NO₂, N₂O, N₂, N radical, H₂S, or S.

12. The semiconductor substrate according to claim 10, wherein the deposition film has a multi-layer structure with two or more layers.

13. The semiconductor substrate according to claim 10, wherein the deposition film has a deposition thickness of 500 Å or less, a resistivity of 300 μΩ·cm or less, a deposition rate of 0.34 Å/cycle or more, a density of 4.0 g/cm³ or more, and an iodine atom of 50 counts/s or more as measured by SIMS.

14. A semiconductor device comprising the semiconductor substrate according to claim 8.
